(19) United States
(12) Patent Application Publication
(10) Pub. No.: US 2013/0127311 A1
(43) Pub. Date: May 23, 2013

(54) ELECTRONIC DEVICE ENCLOSURE WITH BRACKET FOR FAN MODULE

(71) Applicants: PO-WEN CHIU, Tu-Cheng (TW); ZHAN-YANG LI, Shenzhen City (CN); WEN-HU LU, Shenzhen City (CN)

(72) Inventors: PO-WEN CHIU, Tu-Cheng (TW); ZHAN-YANG LI, Shenzhen City (CN); WEN-HU LU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/564,257

(22) Filed: Aug. 1, 2012

(30) Foreign Application Priority Data
Nov. 22, 2011 (CN) 201110373418.3

(51) Int. Cl. H05K 5/03; H05K 7/20; H05K 5/02

(52) U.S. Cl. 312/236; 312/223.1

(57) ABSTRACT

An enclosure includes a chassis and a bracket. The chassis includes a bottom plate and a top plate for the bracket to receive therein. A limiting portion is protruded the bottom plate. The bracket includes a base, a latching member, and a stopping member. The latching member is secured to the base and includes a latching portion. The stopping member is secured to the base and includes a hook. The latching member is rotatable between a first position and a second position relative to the base; when the latching member is in the first position, the hook is engaged with the latching member, the latching portion is engaged with the limiting portion, for preventing the bracket from disengaging from the chassis; when the latching member is in the second position, the hook is elastically deformable to disengage from the latching member, the latching portion is disengaged from the limiting portion.

### BACKGROUND

1. Technical Field

The present disclosure relates to electronic device enclosures, and particularly to an electronic device enclosure with a bracket for fan module.

2. Description of Related Art

Computers include a plurality of electronic components, such as central processing units and power supplies. A large mount of heat is generated from electronic components, so there is usually a fan provided for the power supply to assist in cooling the electronic components. The fan is generally mounted in a bracket, and then the bracket is mounted in the computer enclosures by screws which require the use of a tool. A disassembly or assembly of the bracket is tedious and inconvenient.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of a fan module, an enclosure comprising a chassis and a bracket.

FIG. 2 is an exploded view of the bracket and the fan module of FIG. 1.

FIG. 3 is an isometric view of a stopping member of FIG. 2.

FIG. 4 is a partly assembled view of the enclosure and the fan module of FIG. 2.

FIG. 5 is similar to FIG. 4, but viewed from a different aspect.

FIG. 6 is an assembled view of the enclosure and the fan module of FIG. 1.

FIG. 7 is similar to FIG. 6, but the bracket is detached from the chassis.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

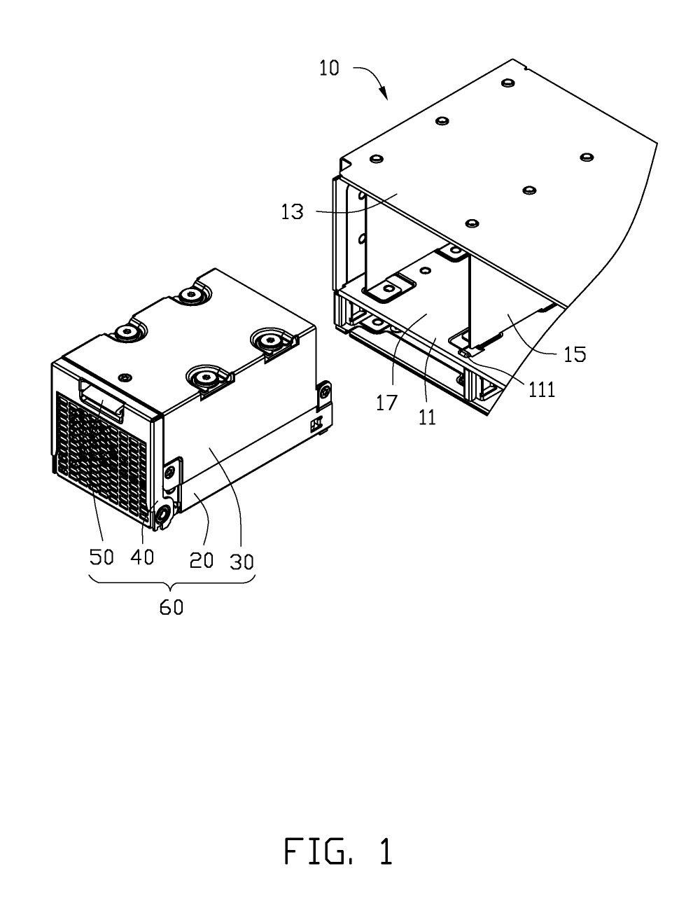

Referring to FIG. 1, an enclosure in accordance with an embodiment includes a chassis 10 and a bracket 60. The bracket 60 is configured to receive a fan module 80.

The chassis 10 includes a bottom plate 11, a top plate 13, and two side plates 15. In one embodiment, the top plate 13 is substantially parallel to the bottom plate 11. The bottom plate 11, the top plate 13, and the two side plates 15 cooperatively define a receiving space 17. A limiting portion 111 protrudes from the bottom plate 11 and is located on a front of one of the two side plates 15.

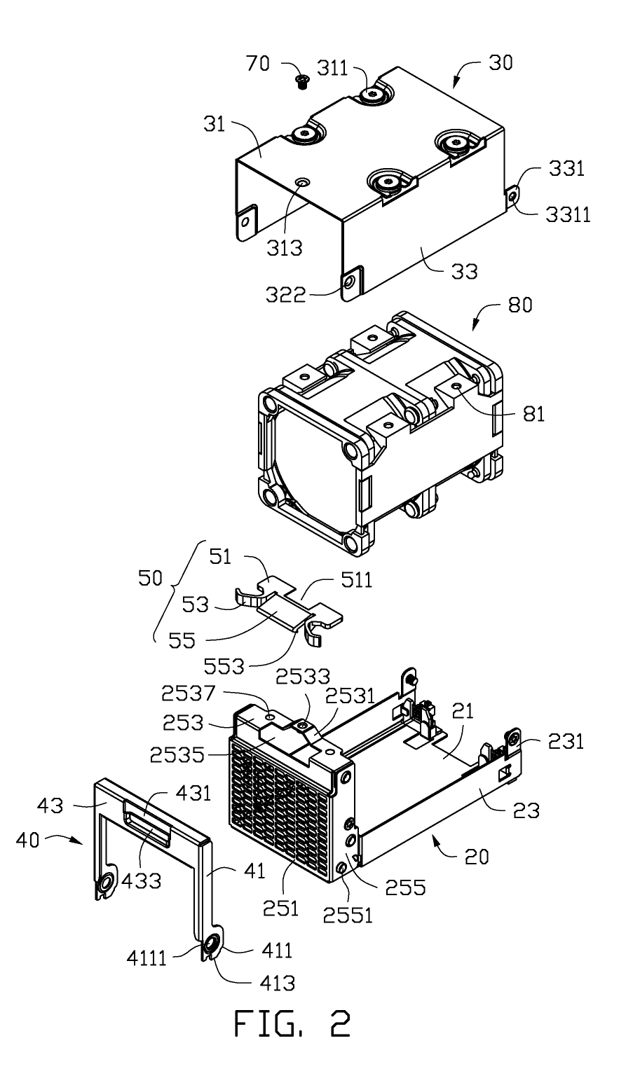

Referring to FIG. 2, the bracket 60 includes a base 20, a cover 30 secured to the base 20, a latching member 40 rotatably secured to the base 20, and a stopping member 50 secured to the base 20. In one embodiment, the bracket 60 is substantially cuboid.

The base 20 includes a bottom wall 21, two sidewalls 23, and a frame 25. The two sidewalls 23 respectively extend from opposite edges of the bottom wall 21. Two securing pieces 231 respectively extend from a back end of the two sidewalls 23. The frame 25 includes a dissipating plate 251, a top flange 253, and two side flanges 255. The dissipating plate 251 extends from a front edge of the bottom wall 21. The top flange 253 extends backwards from a top edge of the dissipating plate 251. The two side flanges 255 extend backwards from opposite side edges of the dissipating plate 251. A platform 2531 is located on the top flange 253 and defines a securing hole 2533. The top flange 253 defines two locking holes 2537 locating on opposite sides of the platform 2531. A cutout 2535 is defined in the top flange 253, extending to the dissipating plate 251. The two side flanges 255 respectively define a first mounting hole (not labeled). A pivot post 2551 protrudes from each of the two side flanges 255, located below each the first mounting hole.

The cover 30 includes a top board 31 and two side boards 33 located on opposite sides of the top board 31. Two absorbing vibration members 311 are located on each of two sides of the top board 31. A positioning hole 313 is defined in a front side of the top board 31. A second mounting hole 322 defines in a front side of each of the two side boards 33. A locking piece 331 extends backward from a back side of each of the two side boards and defines a third mounting hole 3311.

The latching member 40 includes two rotating arms 41 and a blocking board 43 connected to the two rotating arms 41. A rotating portion 411 extends from a low end of each of the two rotating arms 41 and defines a rotating hole 4111. A latching portion 413 extends downwards from a distal end of the rotating portion 411. The blocking board 43 defines an opening 431. A latching piece 433 extends from a bottom edge of the opening 431.

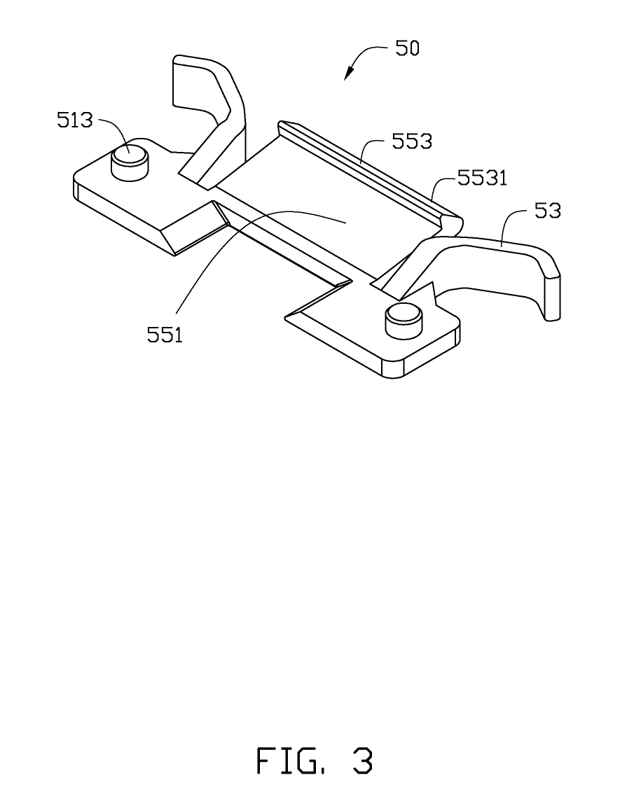

The limiting member 50 includes an installation piece 51, two resilient pieces 53, and a hook 55 located between the two resilient pieces 53. A gap 511 is defined in the installation piece 51 for receiving the platform 2531. Two latching posts 513 (shown in FIG. 3) protrude from a bottom surface of the installation piece 51. Two resilient pieces 53 respectively extend from the installation piece 51 towards opposite directions. In one embodiment, the two resilient pieces 53 substantially have a same shape, and each of the two resilient pieces 53 is substantially arc-shaped. The hook 55 includes a resilient portion 551 (shown in FIG. 3) and a clipping portion 553 located on the resilient portion 551. The clipping portion 553 has a guiding portion 5531 inclined to the installation piece 51.

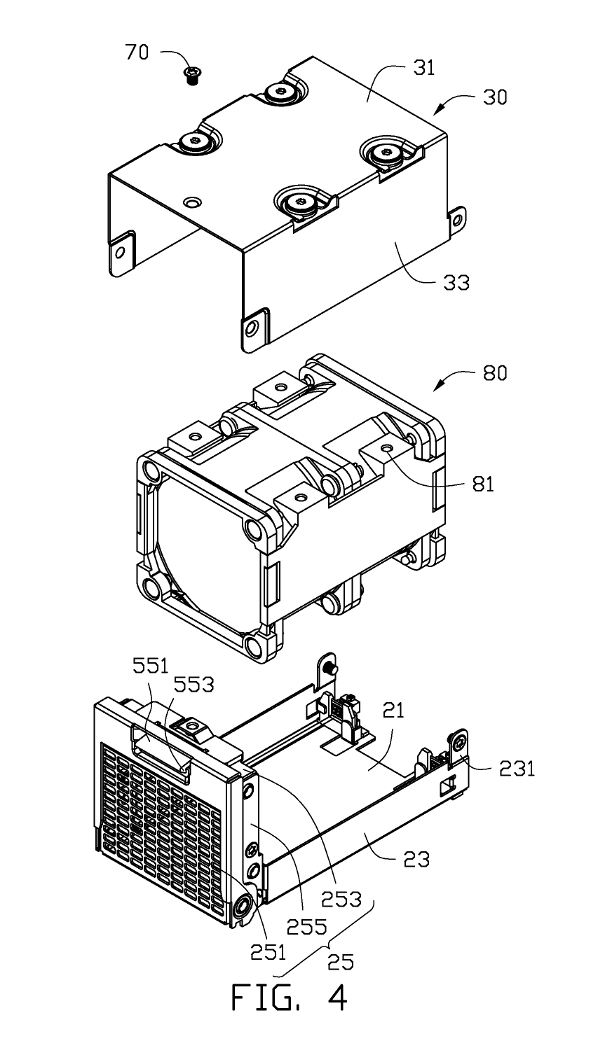

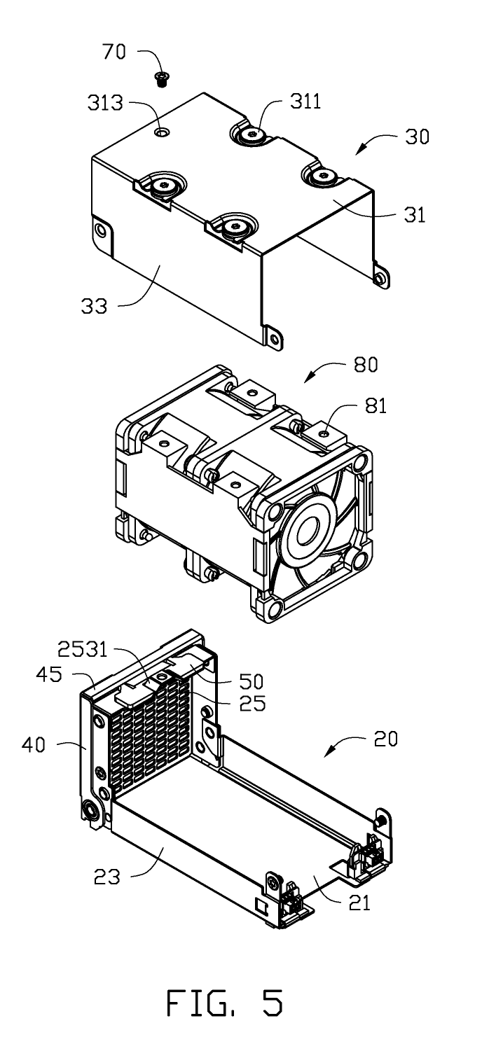

Referring to FIGS. 4 and 5, in assembly, the stopping member 50 is placed on the top flange 253. The two latching posts 513 are respectively inserted into the two locking holes 2537, and the platform 2531 is located on the gap 511. The hook 55 is placed in the cutout 2535.

The pivot post 2551 of the two side flanges 255 is inserted into the rotating hole 4111 of the two rotating arms 41 to secure the latching member 40 to the frame 25 of the base 20. The blocking board 43 is biased to rotate the latching member 40 towards to the frame 25, until the clipping portion 553 extends through the opening 431 to engage with the latching piece 433. The two resilient pieces 53 abut the blocking board 43 for preventing the hook 55 from disengaging from the latching piece 433.

Referring to FIG. 1, the cover 30 is secured to the base 20 by a plurality of screws. The positioning hole 313 is aligned with the securing hole 2533, and a screw is locked into the positioning hole 313 and the securing hole 2533. The top board 31 abuts the installation piece 51 for preventing the latching posts 513 from disengaging from the locking holes 2537. The fan module 80 is located between the cover 30 and the base 20.

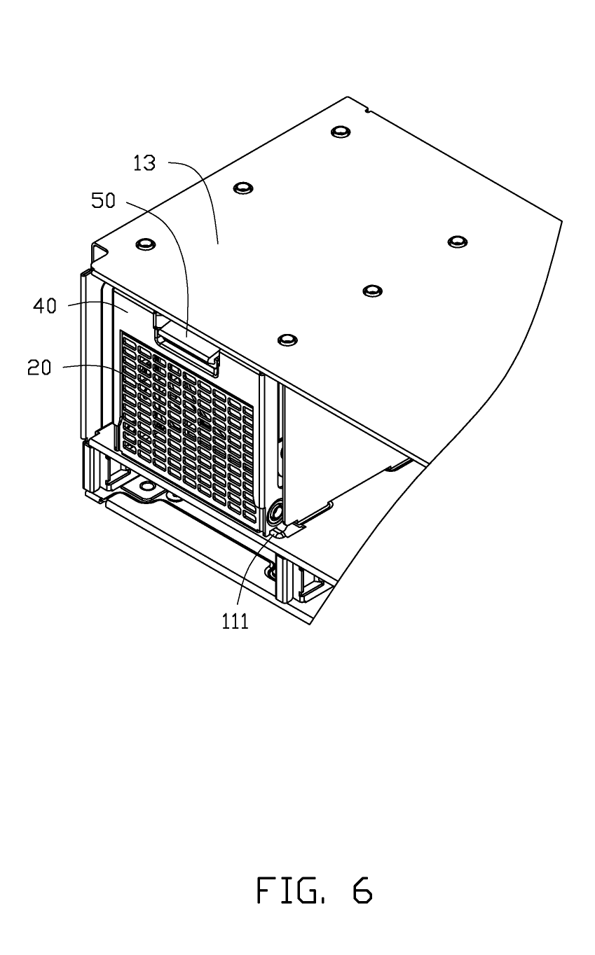

Referring to FIG. 6, in assembly of the bracket 60, a back side of the bracket 60 is inserted into the receiving space 17 of the chassis 10. The hook 55 is put up to disengage the clipping portion 553 from the latching piece 433. The blocking board 43 is biased to rotate the latching member around the pivot posts 2551 towards a first direction that the blocking board 43 is far from the frame 25. The bracket 60 is pushed into the receiving space 17, until the latching portion 413 is over the limiting portion 111. The blocking board 43 is biased to rotate the latching member 40 around the pivot posts 2551 towards a second direction opposite to the first direction. The latching piece 433 resists the guiding portion 5531 to deform the resilient portion 551, until the clipping portion 553 extends through the opening 431 to engage with the latching piece 433. The latching portion 413 is engaged with the limiting portion 111 for preventing the bracket 60 from disengaging from the chassis 10. The two resilient pieces 53 elastically abut the blocking board 43 for preventing the clipping portion 553 from disengaging from the latching piece 433.

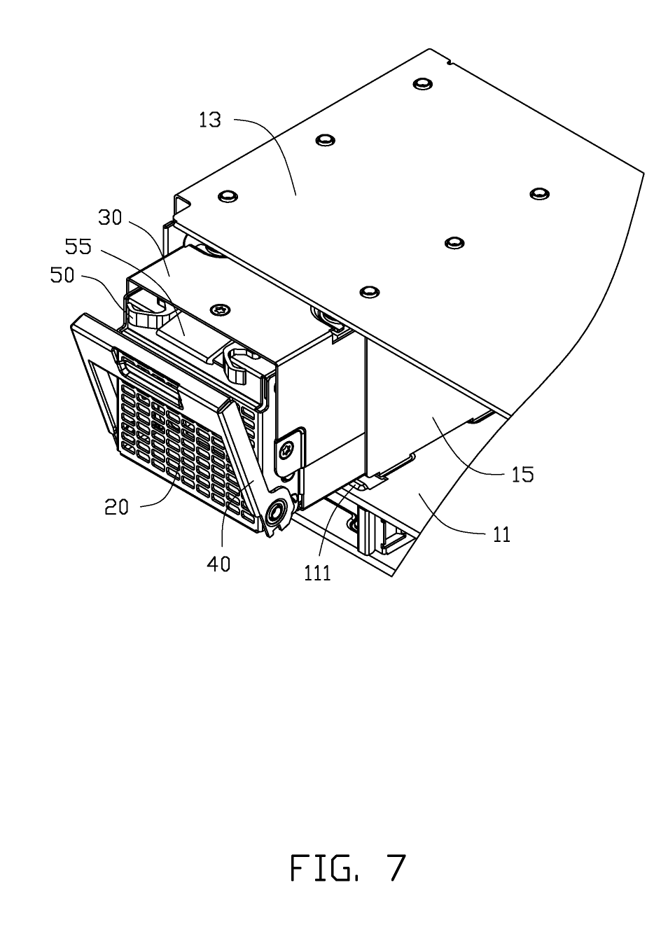

Referring to FIG. 7, in disassembly of the bracket 60, the clipping portion 553 is put up to be disengaged from the latching piece 433. The blocking board 43 is biased to rotate the latching member 40. The latching portion 413 is disengaged from the limiting portion 111. The bracket 60 is pulled out the chassis 10, until the latching portion 413 is over the limiting portion. The bracket 60 is thereby detached from the chassis 10.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. An enclosure comprising:
a chassis, the chassis comprising a bottom plate and a top plate, a limiting portion protruded from the bottom plate; and
a bracket received between the bottom plate and the top plate, the bracket comprising a base, a latching member, and a stopping member; and the latching member rotatably secured to the base and comprising a latching portion, the stopping member secured to the base and comprising a hook;
wherein the latching member is rotatable between a first position and a second position relative to the base; when the latching member is in the first position, the hook is engaged with the latching member, and the latching portion is engaged with the limiting portion, for preventing the bracket from disengaging from the chassis; and when the latching member is in the second position, the hook is elastically deformable to disengage from the latching member, and the latching portion is disengaged from the limiting portion.

2. The enclosure of claim 1, wherein the base comprises a frame, the frame comprises two side flanges, a pivot portion is located on each of the two side flanges, the latching member comprise two rotating arms, a rotating hole is defined in each of the two rotating arms for the pivot portion to engage therein to secure the latching member to the base.

3. The enclosure of claim 2, wherein the base further comprises a blocking board connected to the two rotating arms, an opening is defined in the blocking board, and a latching piece extends from the blocking board; and the hook comprises a clipping portion, and the clipping extends through the opening to engage with the latching piece.

4. The enclosure of claim 3, wherein the hook further comprises a resilient portion, and the resilient portion is elastically deformable to disengage the clipping portion from the latching piece.

5. The enclosure of claim 3, wherein the clipping portion has a guiding portion, and the guiding portion is an inclined surface.

6. The enclosure of claim 2, wherein the stopping member further comprises two resilient pieces located opposite sides of the hook, and the two resilient pieces are capable of abutting the latching member, for preventing the hook from disengaging from the latching member.

7. The enclosure of claim 6, wherein the stopping member further comprises an installation piece, two latching posts are located on the installation piece, the frame comprises a top flange, two locking holes are located on the top flange, and each of the two latching posts is engaged in each of the two locking holes.

8. The enclosure of claim 6, wherein the two resilient pieces are substantially arc-shaped.

9. The enclosure of claim 7, wherein the frame further comprises a dissipating plate connected to the top flange; and the dissipating plate defines a cutout extending to the top flange, and the hook is located on the cutout.

10. The enclosure of claim 7, further comprising a cover secured to the base, wherein the cover comprises a top board; a platform is located on the top flange; and the top board is secured to the platform and abuts the stopping member, for preventing the two latching posts from disengaging from the two locking holes.

11. An enclosure comprising:
a chassis, the chassis comprising a bottom plate and a top plate, a limiting portion protruded from the bottom plate; and
a bracket received between the bottom plate and the top plate, the bracket comprising a base, a latching member, and a stopping member; the latching member rotatably secured to the base and comprising a rotating arms, a latching portion extending from the rotating arms, and the stopping member secured to the base and comprising a hook;
wherein the latching member is rotatable between a first position and a second position relative to the base; when the latching member is in the first position, the hook is engaged with the latching member, and the latching portion is engaged with the limiting portion, for preventing the bracket from disengaging from the chassis; and when the latching member is in the second position, the hook is elastically deformable to disengage from the latching member, and the latching portion is disengaged from the limiting portion.

12. The enclosure of claim 11, wherein the base comprises a frame, the frame comprises two side flanges, a pivot portion is located on each of the two side flanges, the latching member comprise two rotating arms, and a rotating hole is defined in each of the two rotating arms for the pivot portion to engage therein to secure the latching member to the base.

13. The enclosure of claim 12, wherein the base further comprises a blocking board connected to the two rotating arms, an opening is defined in the blocking board, a latching piece extends from the blocking board; the hook comprises a clipping portion, and the clipping extends through the opening to engage with the latching piece.

14. The enclosure of claim 13, wherein the hook further comprises a resilient portion, and the resilient portion is elastically deformable to disengage the clipping portion from the latching piece.

15. The enclosure of claim 13, wherein the clipping portion has a guiding portion, and the guiding portion is an inclined surface.

16. The enclosure of claim 12, wherein the stopping member further comprises two resilient pieces located opposite sides of the hook, and the two resilient pieces are capable of abutting the latching member, for preventing the hook from disengaging from the latching member.

17. The enclosure of claim 16, wherein the stopping member further comprises an installation piece, two latching posts are located on the installation piece, the frame comprises a top flange, two locking holes are located on the top flange, and each of the two latching posts is engaged in each of the two locking holes.

18. The enclosure of claim 16, wherein the two resilient pieces are substantially arc-shaped.

19. The enclosure of claim 17, wherein the frame further comprises a dissipating plate connected to the top flange, and the dissipating plate defines a cutout extending to the top flange, and the hook is located on the cutout.

20. The enclosure of claim 17, further comprises a cover secured to the base, the cover comprises a top board, a platform is located on the top flange, and the top board is secured to the platform and abuts the stopping member, for preventing the two latching posts from disengaging from the two locking holes.
